(19) United States
(12) Patent Application Publication
(10) Pub. No.: US 2016/0204013 A1
(43) Pub. Date: Jul. 14, 2016

(54) ADAPTABLE CASETTE HOLDER

(71) Applicant: CAMTEK LTD., Migdal-Haemek (IL)

(72) Inventors: Arnon Ben-Natan, Kiryat Tiv'on (IL); Yonatan Gorel, Nesher (IL)

(21) Appl. No.: 14/994,162

(22) Filed: Jan. 13, 2016

Related U.S. Application Data
(60) Provisional application No. 62/103,094, filed on Jan. 14, 2015.

(51) Int. Cl. H01L 21/677

(52) U.S. Cl. CPC H01L 21/67706; H01L 21/6773

(57) ABSTRACT

An adaptable cassette holder that may include an interface; an interface holder for holding the interface; multiple recesses formed in the interface; multiple movable cassette holders that positioned at least partially within the multiple recesses; and wherein the movable cassette holders are movable between different positions that correspond to different area of the bottom of the cassette from each other.

### CROSS REFERENCE TO RELATED APPLICATIONS

This application claims priority from U.S. provisional patent Ser. No. 62/103,094 filing date Jan. 14, 2015, which is incorporated herein by reference.

### BACKGROUND OF THE INVENTION

Substrates are usually stored in cassettes. The cassettes are loaded to inspection or metrology systems via load ports. The system that may be used for inspection of substrates usually includes a substrate loader. The substrate loader usually has a pre-aligner and a robotic arm that unloads substrates from the cassette and loads (returns) substrates to the cassette.

There are different kinds of wafers cassettes—such as bare wafers cassette (such as FUOP), and framed wafers cassette also known as PD (Post Dicing) wafers cassette.

Originally, load port device can handle only FUOP. When handle PD cassette, there is a need to place adapter manually.

Due to usage of the OHT (overhead transportation) of cassettes that can be mixed in inspection and production of wafers industries, there is a strong requirement for the universal load port that is adapted to be loaded with different types of cassettes without a need of manual configuration.

During the provision of the cassette to the system the cassette should be firmly held by the tool and should be positioned in an exact location.

There are cassettes of many sizes that suites for substrates of different types and sizes and till now each cassette holder was tailored to a single size of cassettes.

Today there is a lack of standardization of a filed PD cassettes. When a cassette is loaded the cassette shall be place in a solid way and accurately to suit the cassette loader. Due to lack of standardization each time there was a need for manual adapting of the cassette holder to a given customers cassette.

### SUMMARY

An adaptable cassette holder may include an interface, an interface holder for holding the interface, multiple recesses formed in the interface, multiple movable cassette holders that positioned at least partially within the multiple recesses. The movable cassette holders may be movable between different positions that correspond to expected locations of different areas of the cassette bottom.

The cassettes differ from each other by at least one out of size and type.

A plurality of movable cassette bottoms of the multiple movable cassette holders may be positioned within each recess of the multiple recesses.

The multiple movable cassette holders may be detachably coupled to the interface.

The multiple movable cassette holders may be configured to move independently from each other.

The adaptable cassette holder may include rails. The multiple movable cassette holders move on the rails.

Rails positioned within a given recess may be parallel to each other.

The adaptable cassette holder may include at least one cassette sensor for sensing at least one parameter out of a size of a cassette, an identity of the cassette and a type of the cassette while the cassette is supported by the adaptable cassette holder.

The adaptable cassette holder may include position sensors for sensing positions of a group of movable cassette holders of the multiple movable cassette holders.

The adaptable cassette holder may include motors for moving movable leg holders of the group to desired locations that match expected location of different areas of the cassette bottom of a given cassette.

A multiple-type cassette holder may include a first set of interfacing elements that match a cassette of a first type, a second set of interfacing elements that match a cassette of a second type, a first set of cassette sensors for sensing a positioning of a cassette of the first type on the multi-type cassette holder and a second set of cassette sensors for sensing a positioning of a cassette of the second type on the multi-type cassette holder.

The first set of interfacing elements may include a group of pins that may be spaced apart from each other. The second set of interfacing elements may include a group of supporting elements that surrounds the group of pins.

The first set of cassette sensors may be surrounded by the second set of interfacing elements and may be positioned between the cassette sensors of the second set of cassette sensors.

The first set of cassette sensors may include opto-mechanical sensors and wherein the second set of sensors may include pressure sensors.

A method for supporting a cassette by an adjustable cassette holder may include determining or receiving desired locations of movable cassette holders, positioning movable cassette holders in the desired locations and supporting a cassette by the movable cassette holders.

### BRIEF DESCRIPTION OF THE INVENTION

The present invention will be understood and appreciated more fully from the following detailed description taken in conjunction with the drawings in which:

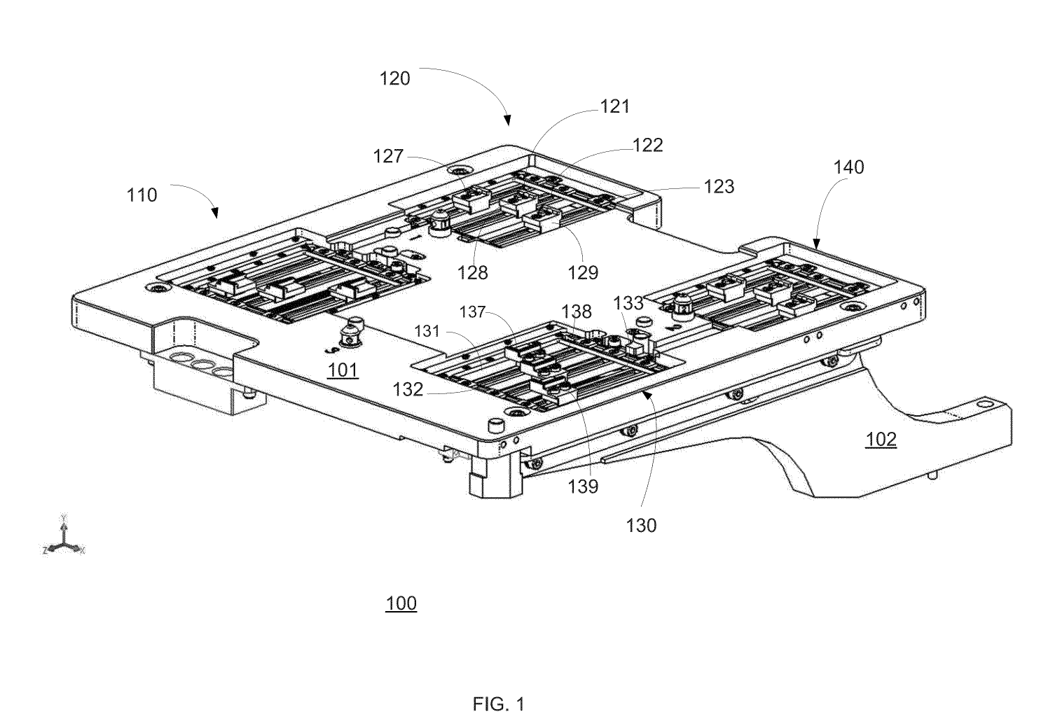

FIG. 1 is an isometric view of an interface and an interface holder of the adaptable cassette holder according to an embodiment of the invention;

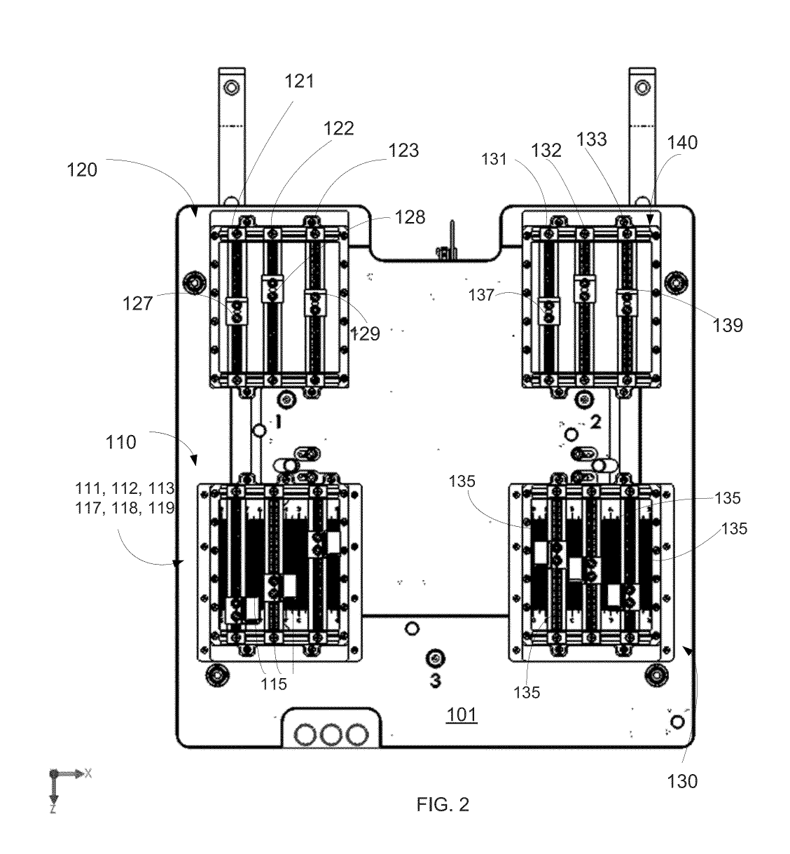

FIG. 2 is a top view of an interface and an interface holder of the adaptable cassette holder according to an embodiment of the invention;

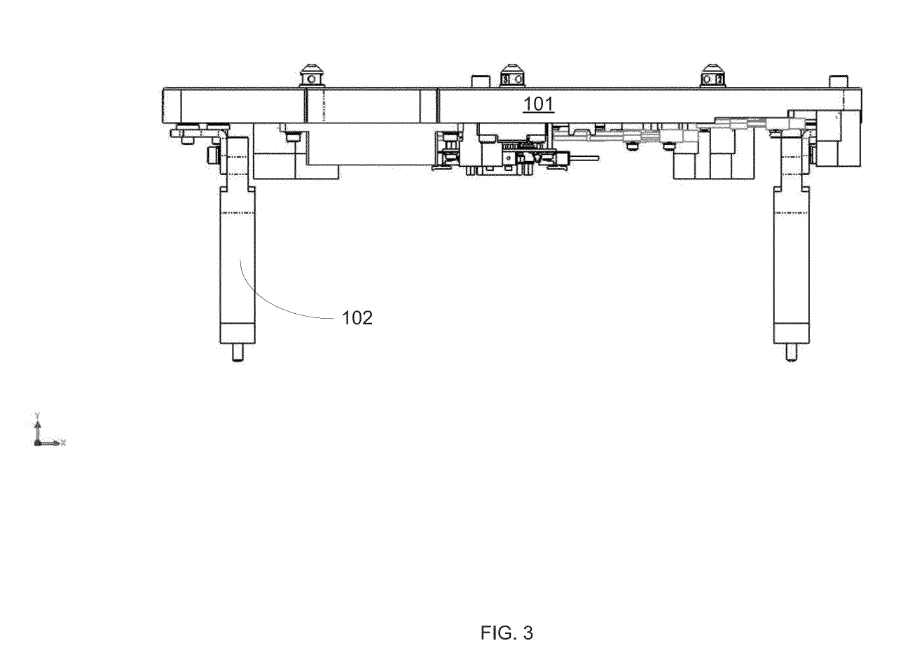

FIG. 3 is a front view of an interface and an interface holder of the adaptable cassette holder according to an embodiment of the invention;

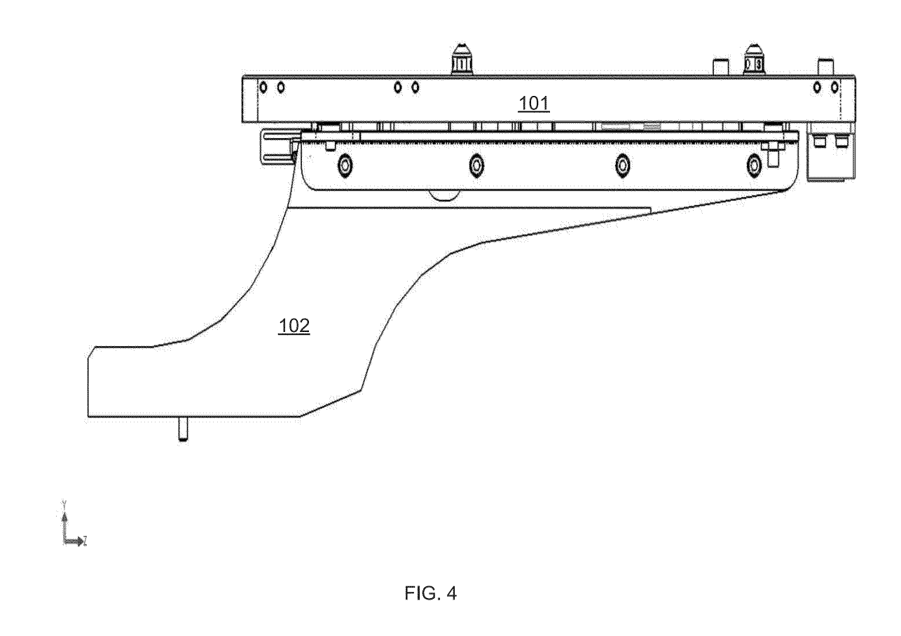

FIG. 4 is a side view of an interface and an interface holder of the adaptable cassette holder according to an embodiment of the invention;

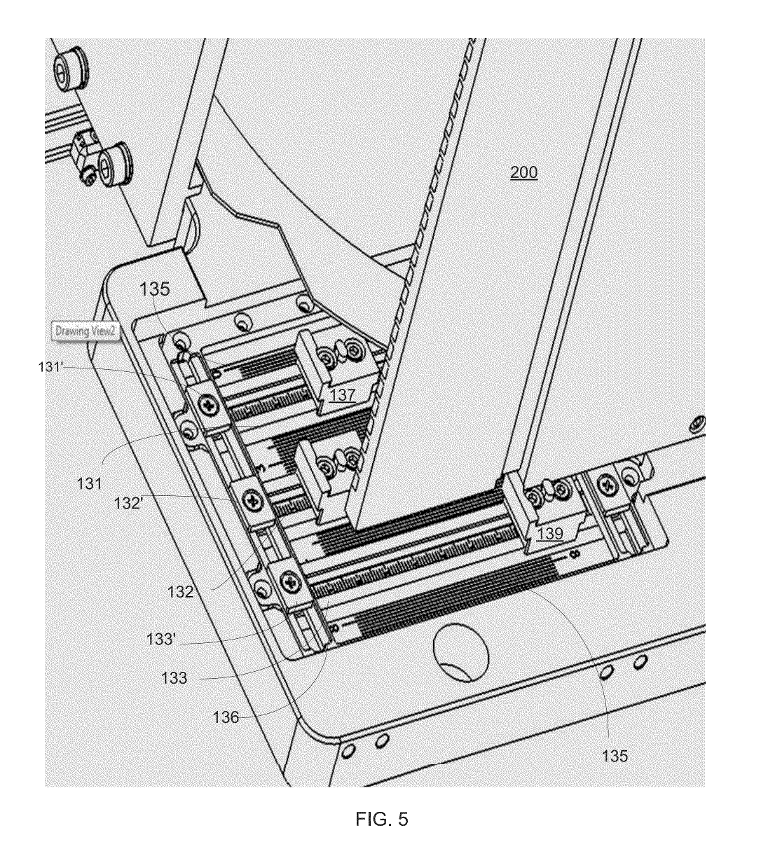

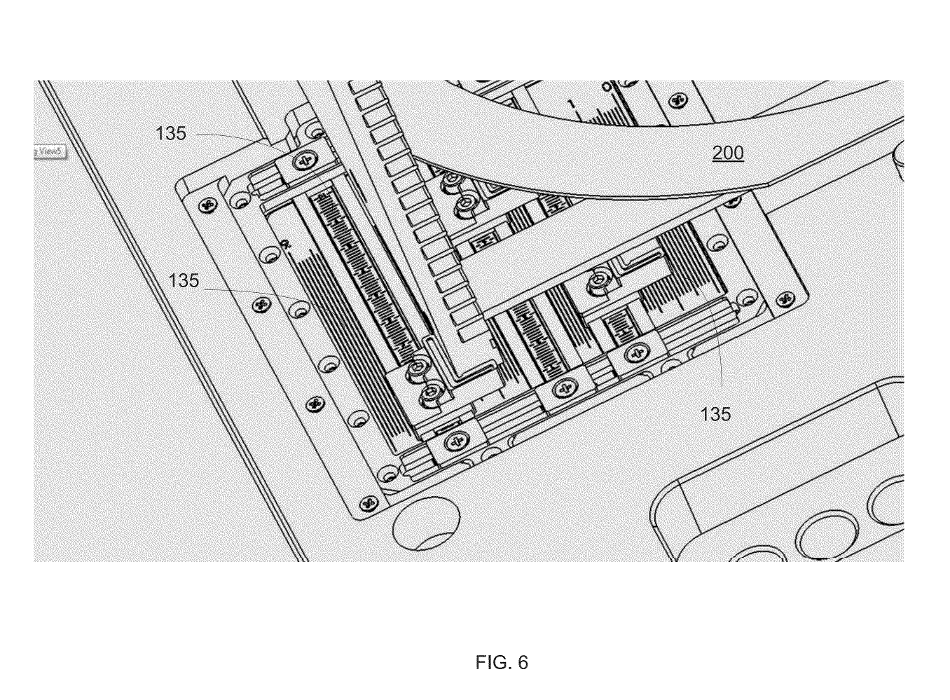

FIGS. 5 and 6 illustrate one leg of a cassette that is supported by one holding element of the adaptable cassette holder according to an embodiment of the invention;

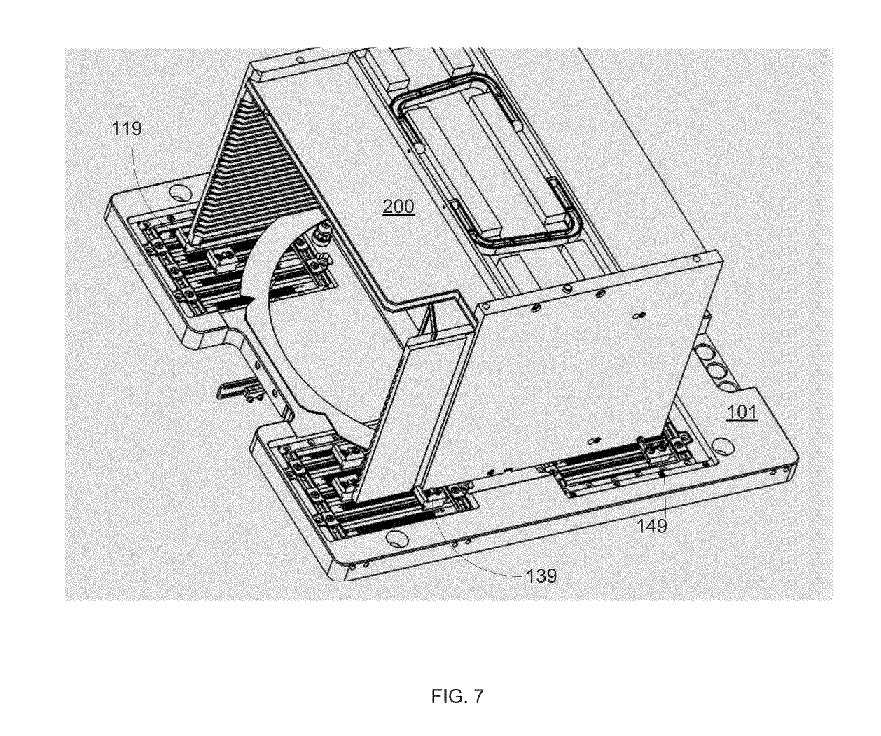

FIG. 7 illustrates a cassette that is supported by the adaptable cassette holder according to an embodiment of the invention;

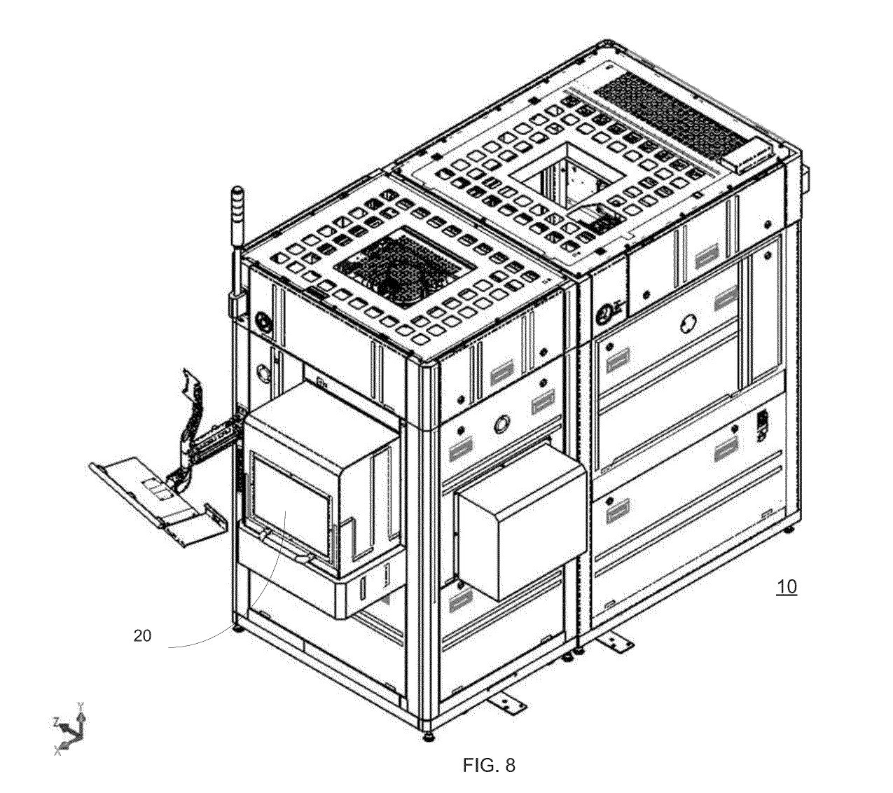

FIG. 8 illustrates an inspection tool with its load port closed by cover according to an embodiment of the invention;

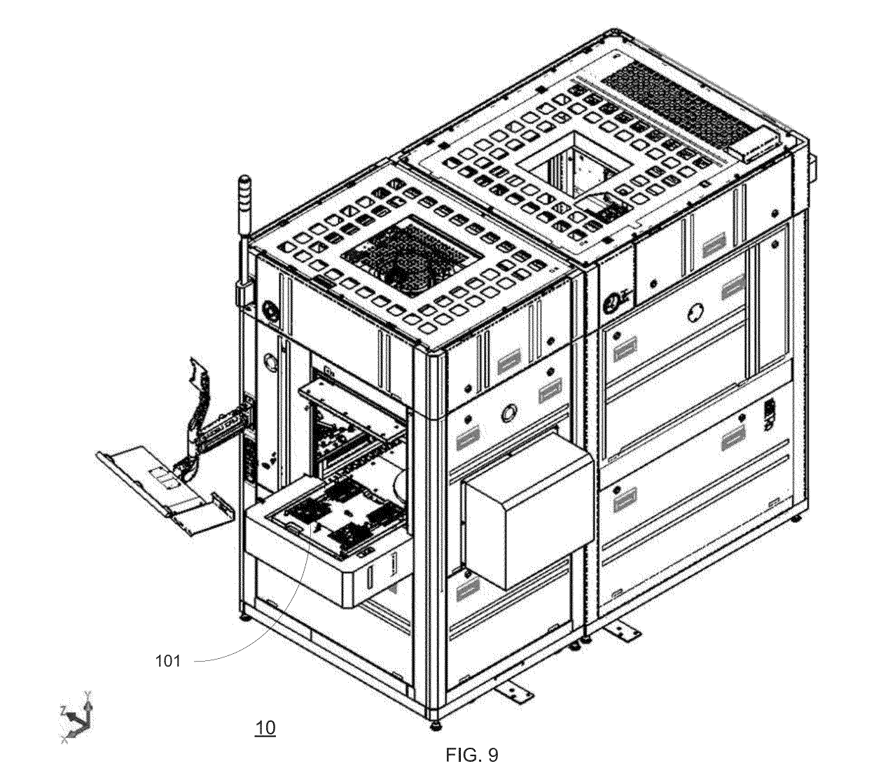

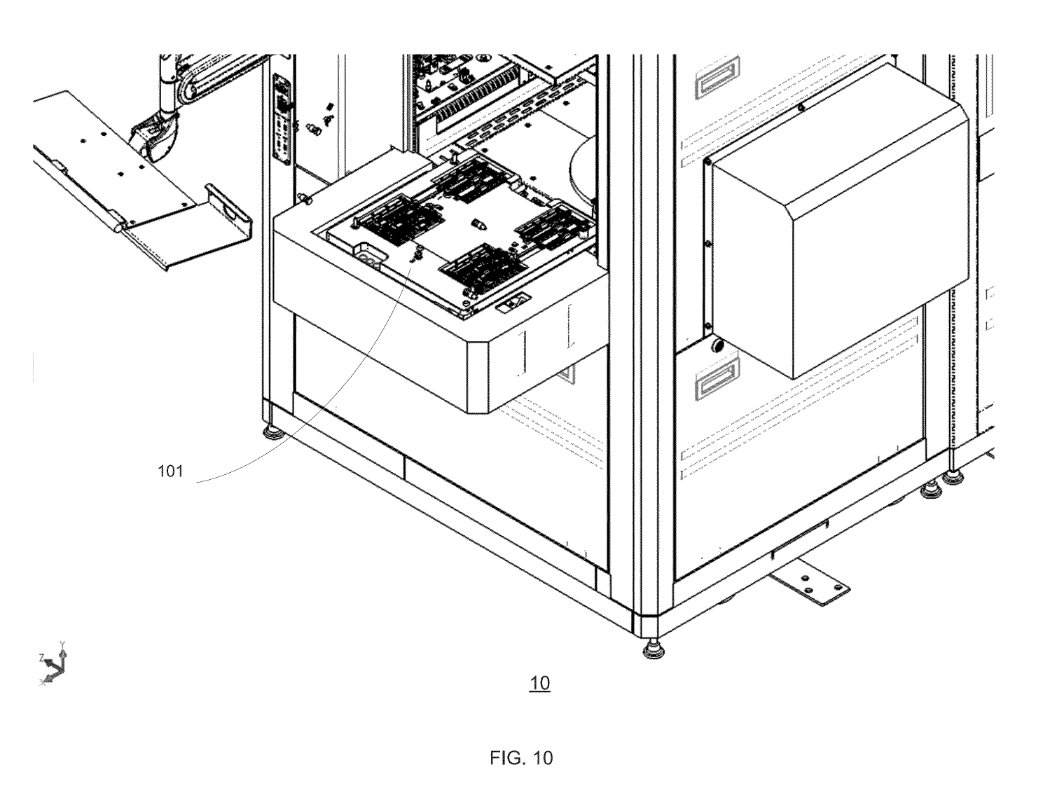

FIGS. 9 and 10 illustrate an inspection tool with its load port open and exposing the adaptable cassette holder according to an embodiment of the invention;

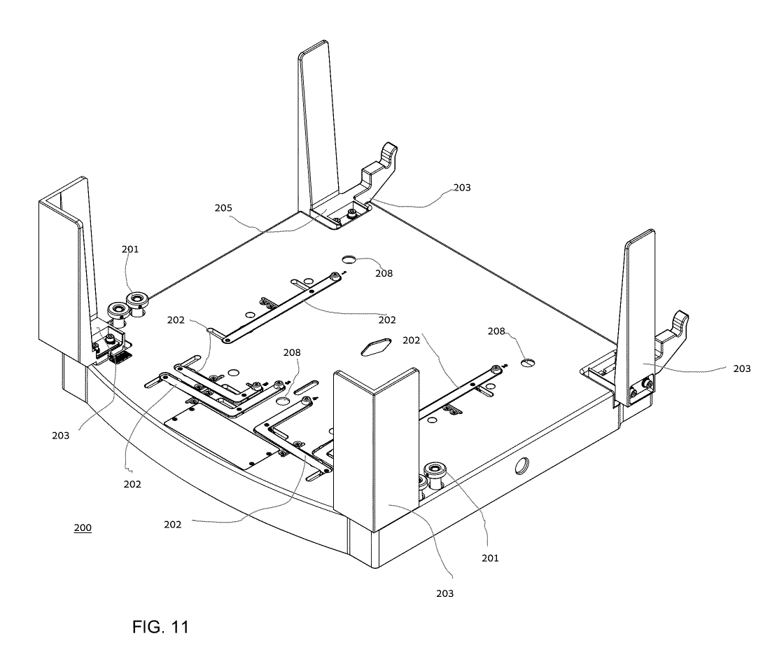

FIG. 11 is an isometric view of a multi-type cassette holder according to an embodiment of the invention;

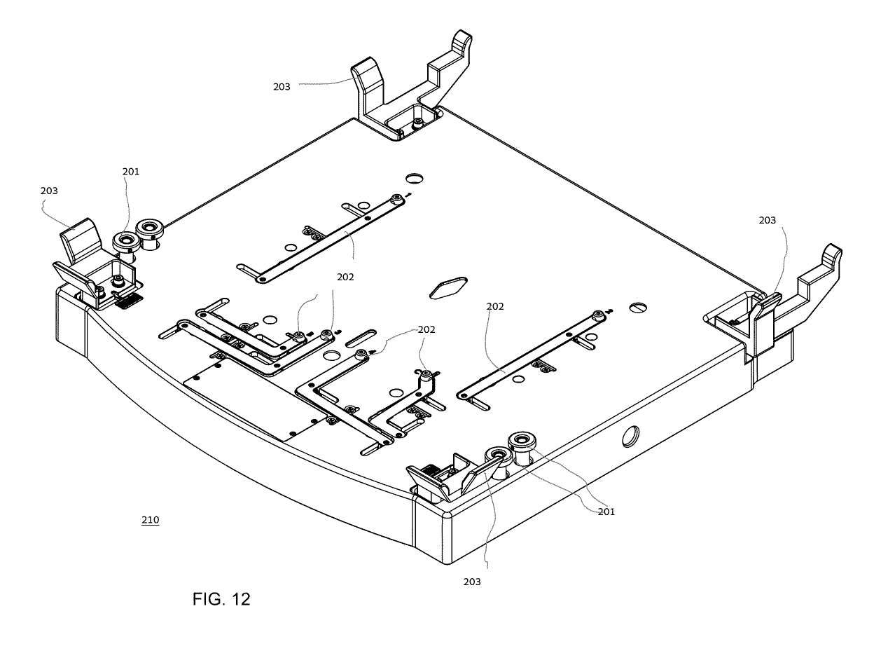

FIG. 12 is an isometric view of a multi-type cassette holder according to an embodiment of the invention;

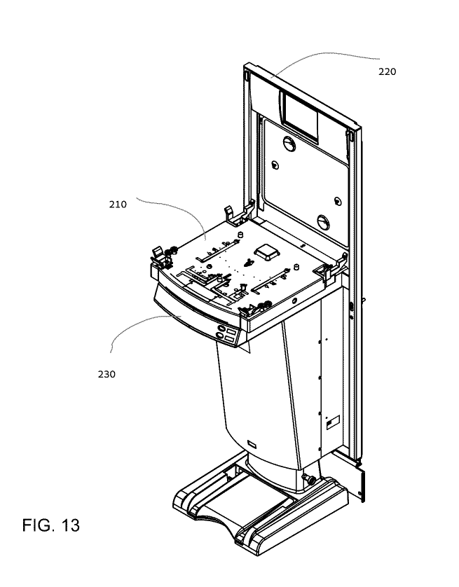

FIG. 13 is an isometric view of a load port and a multi-type cassette holder according to an embodiment of the invention;

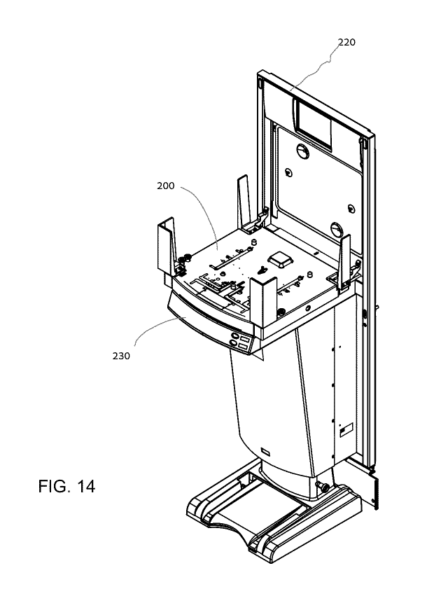

FIG. 14 is an isometric view of a load port and a multi-type cassette holder according to an embodiment of the invention;

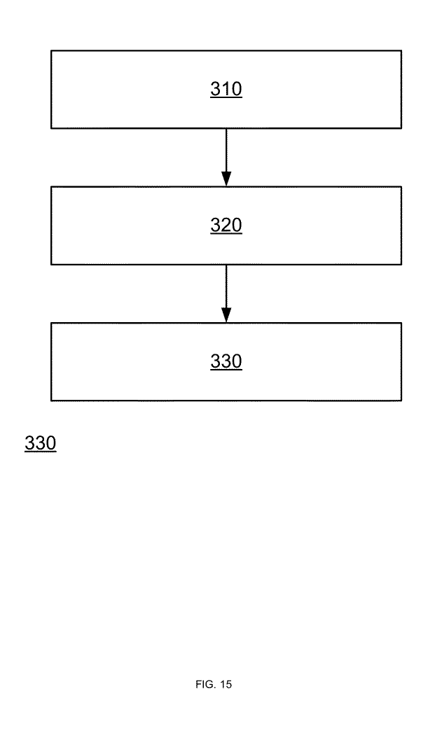

FIG. 15 illustrates a method according to an embodiment of the invention; and

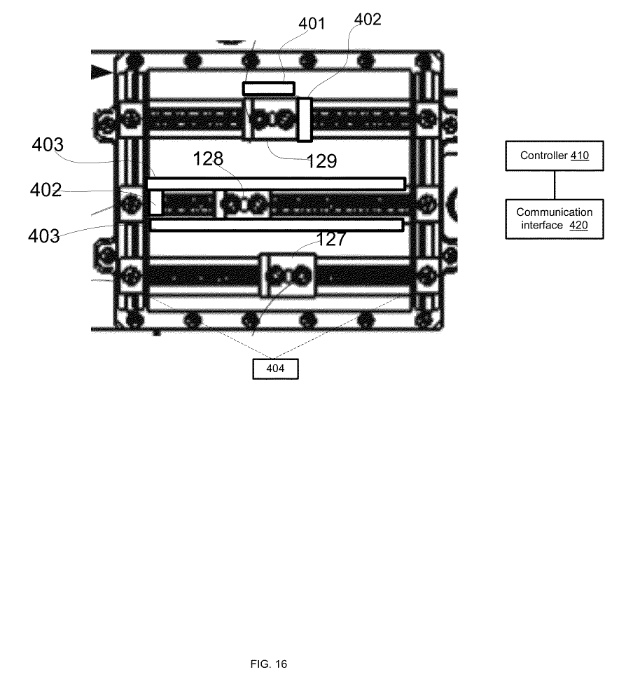

FIG. 16 is a top view of a part of an interface according to an embodiment of the invention.

### DETAILED DESCRIPTION OF THE INVENTION

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

In the following specification, the invention will be described with reference to specific examples of embodiments of the invention. It will, however, be evident that various modifications and changes may be made therein without departing from the broader spirit and scope of the invention as set forth in the appended claims.

There is provided an adaptable cassette holder that may support cassettes of different sizes thus providing flexibility of placement of any cassette type due to unique flexibility of stoppers (rear, front and side stoppers), sensors for recognizing the cassette type automatically and the correct placement of the given cassette. The adaptable cassette holder may support cassettes of different sizes and of different types—including, for example, cassettes for storing any type of substrates—such as but not limited to diced wafers, bare wafers, any size of wafers, any other kind of flat substrates.

The adaptable cassette holder may interface with (or included in) tools of different types. An inspection tool is provided only as a non-limiting example.

In the following text there is a reference to cassette legs and to cassette leg holders. The cassette legs are merely a non-limiting example to different areas of the cassette and especially different areas of the bottom of the cassette. Accordingly—each cassette leg holder is a non-limiting example to a cassette holder. The bottom of the cassette may be flat or may be non-flat. Multiple cassette holders can support different parts of the bottom of the cassette bottom. It is noted that one or more cassette holder may support a sidewall of the cassette.

FIG. 1 is an isometric view of an interface 101 and an interface holder 102 of the adaptable cassette holder according to an embodiment of the invention. FIG. 2 is a top view of an interface 101 and an interface holder 102 of the adaptable cassette holder according to an embodiment of the invention. FIG. 3 is a front view of an interface 101 and an interface holder 102 of the adaptable cassette holder according to an embodiment of the invention. FIG. 4 is a side view of an interface 101 and an interface holder 102 of the adaptable cassette holder according to an embodiment of the invention. FIGS. 5 and 6 illustrate one leg of a cassette 200 that is supported by one holding element of the adaptable cassette holder according to an embodiment of the invention. FIG. 7 illustrates a cassette 200 that is supported by the adaptable cassette holder according to an embodiment of the invention. FIG. 8 illustrates an inspection tool 10 with its load port closed by cover 20 according to an embodiment of the invention. FIGS. 9 and 10 illustrate an inspection tool 10 with its load port open and exposing the adaptable cassette holder according to an embodiment of the invention.

The interface 101 is shown as having four recesses 110, 120, 130 and 140. In each recess there are three movable cassette leg holders 117, 118, 119, 127, 128, 129, 137, 138, 139, 147, 148 and 149 respectively. These cassette leg holders interface with the cassette legs and support the cassette 200. Four legged cassettes are supported by four cassette leg supporters—one from each recess. The cassette leg holders are spaced apart from each other, can be moved within the recesses and can also be removed from the interface 101.

Having multiple cassette leg holders per recess allows a user (after an initial adaptation of the cassette leg holders) to replace between cassettes of different types without the need of adjusting the adjustable cassette holder between each one of the replacements.

The ability to move the cassette leg holders as well as the provision of multiple cassette leg holders per recess allows an adaptation of the adaptable cassette holder to hold different cassettes.

The movable cassette leg holders 117, 118, 119, 127, 128, 129, 137, 138, 139, 147, 148 and 149 are positioned on rails 111, 112, 113, 121, 122, 123, 131, 132, 133, 141, 142 and 143 and may be moved along these rails. The rails may be connected to the interface 101 via interfacing elements that allow to change the position of the rails and even to remove the rails. In FIG. 5 rails 131, 132 and 133 are detachably connected to the interface 101 via fastening elements 131′, 132′ and 133′ that may move along interfacing rail 136. By unscrewing the screws of fastening elements 131′, 132′ and 133′ the locations of the fastening elements and thereby the locations of rails can be changed—and they may also be removed.

The cassette leg holders can be fixed to their location after being positioned in the desired position. FIG. 5 illustrates each rail 131, 132 and 133 as including a pair of screws.

The rails and their vicinity include markings (such as vertical and horizontal rulers and/or grids 135) for providing indication about the location of the cassette leg holders—this may be used when positioned the cassette leg holder at a desired location.

The positioning of the cassette leg holder may be done manually or automatically.

In case of automatic positioning the inspection tool will have position sensors for determining the location of the cassette leg holders (may be optical sensors that may benefit from the markings, may be radiation based location sensors), as well as motors for changing the position of the cassette leg holders. The location and even the selection of the cassette leg holders may be determined based upon a cassette type and/or a cassette identifier. The cassette type and/or a cassette identifier may be provided to the inspection tool or detected by the inspection tool (by a cassette type detector and/or cassette identifier reader). FIG. 16 illustrates various types of sensors and motors according to various embodiments of the invention.

Position sensor 401 is coupled to the side of movable cassette leg holder 129 while the motor 403 the moves the movable cassette leg holder 129 along a rail is positioned at the back (or front) of movable cassette leg holder 129.

Position sensor 402 is positioned in front of (and without contacting) movable cassette leg holder 128 while the motor 403 the moves the movable cassette leg holder 128 along a rail is positioned at both sides of the rail.

Position sensor 404 is an optical sensor that is spaced apart (above) the movable cassette leg holder 127 while the motor the moves the movable cassette leg holder 127 along a rail is not shown.

The position sensors and/or the motors are coupled to controller 410 that may instruct the motors to move the movable cassette leg holders 127, 128 and 129 to desired locations. The desired locations can be fed to controller 410 by communication interface 420.

There may be provided sensors for sensing the type of the cassettes (position sensors may provide information about the size of the cassette—hence indicate the type of the cassette; cassette identifiers (such as optical readers, RF sensors) may detect the type of the cassette. Such sensors may be used to provide the inspection tool an indication about the type of the cassette—the inspection tool may then tune its operations (for example select a recipe) based upon the sensed type of the cassette. The sensors may be positioned within one or more recess, outside a recess or a combination thereof.

The number of cassette leg holders per recess may differ from three, the number of recesses may differ from four, the cassette holders may move along elements that differ from rails, the cassette leg holder may be positioned at different heights (for example—their height may increase with their distance from the center of interface 101).

There may be provided a method for adjusting an adjustable cassette holder. The method may include determining a desired location of cassette leg holders (this may include selecting which cassette leg holder to use), positioning (if change in position is required) the cassette leg holders in their desired position and supporting a cassette.

According to an embodiment of the invention there may be provided a multi-type cassette holder.

The multi-type cassette holder may support cassettes of different types. The multi-type cassette holder can be attached to a load port and may include multiple sensors (or triggers/pressure buttons) which their location is based on the different shapes of wafer cassettes exterior shape in order to determine what kind of cassette is currently being loaded thereon. This allows a detecting of the specific kind of wafer cassette and thus enabled to inspect different kinds of wafers.

The multi-type cassette holder uses multiple pressure points (info pad) that act as sensors (or triggers/pressure buttons).

The location of these pressure points is predetermined based on the baseline perimeter of known wafer cassettes.

When each wafer cassette is mounted onto the load port, each different kind of cassette triggers different pressure points.

Once certain pressure points are pressed, the load port sends a signal to the inspection device, notifying the device that the wafer cassette is of “X” or “Y” type and then a compatible inspection sequence is initiated by the inspection device.

By using the multi-type cassette holder there is no need to stop the production until a new single-type cassette holder is manufactured.

FIGS. 12 and 13 illustrate multi-type cassette holders according to an embodiment of the invention. FIGS. 14 and 15 illustrate load ports and the multi-type cassette holders according to an embodiment of the invention.

FIG. 12 illustrates multi-type cassette holder that include a first set of interfacing elements 208 (apertures of pins) that match a cassette of a first type, a second set of interfacing elements 203 that match a cassette of a second type; a first set of cassette sensors 202 for sensing a positioning of a cassette of the first type on the multi-type cassette holder; and a second set of cassette sensors 201 for sensing a positioning of a cassette of the second type on the multi-type cassette holder. The interfacing elements 203 may act as stoppers and are replaceable—they are detachably coupled to another part of the interface 101.

The first set of interfacing elements includes a group of pins that are spaced apart from each other. The second set of interfacing elements includes a group of interfacing elements 203 that surrounds the group of pins. The interfacing elements 203 of the second set may include a base that is detacheably connected to multi-type cassette holder. The second set of cassette sensors may be pressure sensors that may be pressed against a bottom of a cassette when the cassette is supported by the second set of interfacing elements. For example the top surface of the cassette sensors of the second set may be above an interfacing bottom part (205) of the group of interfacing elements 203.

The first set of cassette sensors 202 may be opto-mechanical sensors that includes a mechanical element that once pressed by the cassette enters a cavity and changes a propagation of radiation (light, IR) within the cavity.

The first set of cassette sensors 202 may be surrounded by the second set of interfacing elements and may be positioned between the cassette sensors of the second set of cassette sensors.

The multi-type cassette holder 210 of FIG. 12 differs from the multi-type cassette holder 2000 of FIG. 11 by the shape of the second set of interfacing elements.

FIG. 13 illustrates the multi-type cassette holder 2000 of FIG. 11 that is coupled to a load port—and is positioned on part 230 of the load port. The load port also has an additional part 230.

FIG. 14 illustrates the multi-type cassette holder 2000 of FIG. 11 that is coupled to a load port—and is positioned on part 230 of the load port. The load port also has an additional part 230.

FIG. 15 illustrates method 300 according to an embodiment of the invention.

Method 300 includes the steps of (310) determining or receiving desired locations of movable cassette leg holders; (320) positioning movable cassette leg holders in the desired locations; and (330) supporting a cassette by the movable cassette leg holders.

The method can be executed by any of the adaptable cassette holders illustrated in the specification.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Thus, it is to be understood that the architectures depicted herein are merely exemplary, and that in fact many other architectures can be implemented which achieve the same functionality. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

However, other modifications, variations, and alternatives are also possible. The specifications and drawings are, accordingly, to be regarded in an illustrative rather than in a restrictive sense.

The word “comprising” does not exclude the presence of other elements or steps then those listed in a claim. It is understood that the terms so used are interchangeable under appropriate circumstances such that the embodiments of the invention described herein are, for example, capable of operation in other orientations than those illustrated or otherwise described herein.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe.

Thus, these terms are not necessarily intended to indicate temporal or other prioritization of such elements. The mere fact that certain measures are recited in mutually different claims does not indicate that a combination of these measures cannot be used to advantage.

We claim:

1. An adaptable cassette holder, that comprises:
an interface;
an interface holder for holding the interface;
multiple recesses formed in the interface;
multiple movable cassette holders that positioned at least partially within the multiple recesses; and
wherein the movable cassette holders are movable between different positions that correspond to expected locations of different areas of the cassette bottom.

2. The adaptable cassette holder according to claim 1 wherein the cassettes differ from each other by at least one out of size and type.

3. The adaptable cassette holder according to claim 1, wherein a plurality of movable cassette bottoms of the multiple movable cassette holders are positioned within each recess of the multiple recesses.

4. The adaptable cassette holder according to claim 1, the multiple movable cassette holders are detacheably coupled to the interface.

5. The adaptable cassette holder according to claim 1, the multiple movable cassette holders are configured to move independently from each other.

6. The adaptable cassette holder according to claim 1, comprising rails, wherein the multiple movable cassette holders move on the rails.

7. The adaptable cassette holder according to claim 6, wherein rails positioned within a given recess are parallel to each other.

8. The adaptable cassette holder according to claim 1, comprising at least one cassette sensor for sensing at least one parameter out of a size of a cassette, an identity of the cassette and a type of the cassette while the cassette is supported by the adaptable cassette holder.

9. The adaptable cassette holder according to claim 1, comprising position sensors for sensing positions of a group of movable cassette holders of the multiple movable cassette holders.

10. The adaptable cassette holder according to claim 9, comprising motors for moving movable leg holders of the group to desired locations that match expected location of different areas of the cassette bottom of a given cassette.

11. A multiple-type cassette holder, that comprises:
a first set of interfacing elements that match a cassette of a first type;
a second set of interfacing elements that match a cassette of a second type;
a first set of cassette sensors for sensing a positioning of a cassette of the first type on the multi-type cassette holder; and
a second set of cassette sensors for sensing a positioning of a cassette of the second type on the multi-type cassette holder.

12. The multiple-type cassette holder according to claim 11 wherein the first set of interfacing elements comprises a group of pins that are spaced apart from each other; and
wherein the second set of interfacing elements comprises a group of supporting elements that surrounds the group of pins.

13. The multiple-type cassette holder according to claim 11 wherein the first set of cassette sensors are surrounded by the second set of interfacing elements and are positioned between the cassette sensors of the second set of cassette sensors.

14. The multiple-type cassette holder according to claim 11 wherein the first set of cassette sensors comprises opto-mechanical sensors and wherein the second set of sensors comprises pressure sensors.

15. A method for supporting a cassette by an adjustable cassette holder, the method comprise determining or receiving desired locations of movable cassette holders;
positioning movable cassette holders in the desired locations; and supporting a cassette by the movable cassette holders.
